(19) United States
(12) Patent Application Publication
(10) Pub. No.: US 2013/0128923 A1
(43) Pub. Date: May 23, 2013

(54) DEVICE FOR RAISING TEMPERATURE AND METHOD FOR TESTING AT ELEVATED TEMPERATURE

(71) Applicant: Kenichi Sawada, Osaka-shi (JP)

(72) Inventor: Kenichi Sawada, Osaka-shi (JP)

(73) Assignee: SUMITOMO ELECTRIC INDUSTRIES, LTD., Osaka-shi (JP)

(21) Appl. No.: 13/813,111

(22) PCT Filed: Jul. 26, 2011
(86) PCT No.: PCT/JP2011/066966

§ 371 Date: Jan. 29, 2013

(30) Foreign Application Priority Data
Aug. 4, 2010 (JP) 2010-175456

(51) Int. Cl. G01K 7/01; H01L 29/16

(52) U.S. Cl. CPC G01K 7/01; H01L 29/1608
USPC 374/178; 257/77

(57) ABSTRACT

An external DC power supply 2 feeds a power supply voltage to a drain electrode of a MOSFET 10 constituted by silicon carbide (SiC), and a variable bias voltage generated from thus fed power supply voltage is applied to a gate electrode 13, so as to raise the temperature of the MOSFET 10. To a voltage divided by resistors R3, R4 from the power supply voltage, a change in a voltage divided by resistors R1, R2 from the power supply voltage is amplified by a predetermined negative amplification factor in the MOSFET 20 and added at a drain electrode 21, so that the drain electrode 21 attains a fixed voltage, whereby the bias voltage is held constant.

### TECHNICAL FIELD

The present invention relates to a temperature raising device including a MOSFET constituted by a wide-bandgap semiconductor which heats up as energized by an electric power from an external DC power supply, and a temperature raising test method using the temperature raising device.

### BACKGROUND ART

Temperature characteristic tests for testing whether or not produced semiconductor devices satisfy various specs under predetermined high-temperature environments, sometimes with high-temperature reliability tests including acceleration tests, have conventionally been conducted. As a method for performing temperature characteristic and high-temperature reliability tests for semiconductor devices, Patent Literature 1 discloses one which heats semiconductor devices respectively held by a number of holders on a test board by bringing contactors of a heated conductor member into contact with them from thereabove. There is also a case where semiconductor devices are mounted on a heated test board for a test.

Patent Literature 2 discloses a technique which selects semiconductor devices on an evaluation board installed in a high-temperature bath and heats the selected semiconductor device with a polysilicon heater to the ambient temperature within the high-temperature bath or higher. Patent Literature 3 discloses a technique which cools one surface of a test tray containing a semiconductor device with an electronic cooling device and heats the other surface with an electronic cooling device.

### CITATION LIST

### Patent Literature

Patent Literature 1: Japanese Patent Application Laid-Open No. 2009-53082
Patent Literature 2: Japanese Patent Application Laid-Open No. 2008-122189
Patent Literature 3: Japanese Patent Application Laid-Open No. 2003-315406

### SUMMARY OF INVENTION

### Technical Problem

When a plurality of semiconductor devices are assumed to be tested by the technique disclosed in Patent Literature 1, however, the test board responsible for heating tends to become larger in size, while it is disadvantageous in terms of cost and space efficiency to prepare a plurality of small ones. For testing a semiconductor device which switches at a high frequency of several hundred kHz or above, for example, the technique disclosed in Patent Literature 2 must place the semiconductor device and a driving circuit for the test within the high-temperature bath in order to shorten the wiring length, which makes the test difficult in practice. Since not only the electronic cooling device used for heating is expensive, but also the upper limit for the test temperature is restricted to about 100° C., the technique disclosed in Patent Literature 3 has been unable to conduct tests at a high temperature near or beyond the temperature limit of semiconductor devices made of silicon.

It is an object of the present invention to provide a temperature raising device which is not only small in size, inexpensive, and easy to control the temperature, but can also be employed for a temperature raising test at a temperature beyond the temperature limit of a semiconductor device made of silicon, and a temperature raising test method using the temperature raising device.

### Solution to Problem

The temperature raising device in accordance with one embodiment of the present invention is a temperature raising device comprising a MOSFET having a heat dissipater with a drain electrode to be fed with a voltage from an external DC power supply and a bias circuit for applying a bias voltage to a gate electrode of the MOSFET; wherein the MOSFET is made of a semiconductor material having a bandgap greater than that of silicon; and wherein the bias circuit generates a variable bias voltage from the voltage to be fed to the drain electrode.

When the external DC power supply feeds a voltage to the drain electrode of the MOSFET made of a so-called wide-bandgap semiconductor, a variable bias voltage generated from the fed voltage is applied to the gate electrode. This enables operations using the single external power supply, so that the drain current is controlled variably according to a relatively small electric power. Therefore, the bias voltage is easily changed by a human operation, for example, so that a drain current having a level corresponding to the magnitude of the bias voltage flows in from the external power supply, thereby generating a Joule heat corresponding to the product of the voltage of the external power supply and the drain current, thus changing how much the drain electrode and heat dissipater raise their temperature. Even when the temperature of the drain electrode and heat dissipater exceeds the tolerable temperature of the semiconductor made of silicon, they can operate stably up to near the limit temperature of the wide-bandgap semiconductor constituting the MOSFET.

The temperature raising device in accordance with one embodiment may be constructed such that the DC power supply has a variable output voltage, while the bias circuit generates the bias voltage from a voltage obtained by adding a voltage corresponding to a change in the output voltage and a voltage for canceling the change.

When the output voltage of the DC power supply forming a basis for generating the bias voltage changes in this temperature raising device, the bias voltage is generated from a voltage obtained by adding a voltage changing according to the magnitude of the output voltage and a voltage changing such as to cancel the change in the voltage. For example, to a change in a voltage divided from the output voltage of the DC power supply, a change in a voltage divided separately from the output voltage is amplified by a predetermined negative amplification factor and then added, so as to cancel the change in the output voltage. This generates a bias voltage from a fixed voltage, whereby a constant voltage is applied to the gate electrode regardless of the change in the output voltage from the external power supply.

In the temperature raising device in accordance with one embodiment, the MOSFET may operate in a saturation region.

Since the MOSFET operates in the saturation region in this temperature raising device, the Joule heat generated at the drain electrode becomes substantially proportional to the output voltage of the external power supply applied to the drain electrode.

In the temperature raising device in accordance with one embodiment, the heat dissipater may be molded with a resin.

Since at least the heat dissipater is molded with a resin in this temperature raising device, electric interferences can be prevented from occurring even when the heat dissipater is joined to a metal part of a semiconductor device to be tested, for example.

The temperature raising device in accordance with one embodiment may further comprise an insulator for electrically insulating the heat dissipater.

Since the insulator electrically insulates the heat dissipater in this temperature raising device, electric interferences are prevented from occurring when the insulator is inserted between a metal part of the semiconductor device to be tested and the heat dissipater, for example.

The temperature raising test method in accordance with one embodiment is a method for conducting a temperature raising test of a semiconductor device having a heat dissipater by using the above-mentioned temperature raising device and a DC power supply having a variable output voltage, the method comprising feeding the output voltage of the DC power supply to the drain electrode of the MOSFET constituting the temperature raising device, joining the heat dissipaters of the drain electrode of the MOSFET and semiconductor device to each other, and changing the output voltage and/or the bias voltage applied to the gate electrode of the MOSFET.

This temperature raising method feeds the output voltage of the DC power supply to the drain electrode of the MOSFET of the temperature raising device and, while joining the heat dissipater of the MOSFET and that of the semiconductor device to be tested to each other, at least one of the output voltage of the DC power supply and the bias voltage to be applied to the gate electrode of the MOSFET is changed, so as to adjust how much the temperature is raised. This can efficiently transmit the heat generated by the temperature raising device to the semiconductor device to be tested. When the output voltage of the external power supply and/or the bias voltage is changed to become higher/lower, the quantity of the Joule heat generated at the drain electrode of the MOSFET becomes greater/smaller, so that the semiconductor device to be tested is heated more/less through the heat dissipaters.

In the temperature raising test method in accordance with one embodiment, the MOSFET and the semiconductor device may be surrounded with a heat-shrinkable tube.

This temperature raising test method surrounds the MOSFET of the temperature raising device with a heat-shrinkable tube and heats the heat-shrinkable tube so as to shrink it. This joins the MOSFET and the semiconductor device to be tested closely to each other and reduces the ratio of heat diffusing to the outside air in the Joule heat generated in the MOSFET, thereby improving the temperature raising effect.

### Advantageous Effects of Invention

In the present invention, the drain electrode and heat dissipater of a typical MOSFET constituted by a so-called wide-bandgap semiconductor raise their temperature according to the magnitude of the bias voltage applied to the gate after being generated from the voltage fed to the drain electrode. This enables operations using a single external power supply, whereby the drain current is controlled variably according to a relatively small electric power. Therefore, the bias voltage is easily changed by a human operation, for example, so that a drain current having a level corresponding to the magnitude of the bias voltage flows in from the external power supply, thereby generating a Joule heat corresponding to the product of the voltage of the external power supply and the drain current, thus changing how much the drain electrode and heat dissipater raise their temperature. Even when the temperature of the drain electrode and heat dissipater exceeds the tolerable temperature of the semiconductor made of silicon, the temperature raising device can operate stably up to near the limit temperature of the wide-bandgap semiconductor constituting the MOSFET. This makes the temperature raising device not only small in size, inexpensive, and easy to control the temperature, but also employable for a temperature raising test at a high temperature beyond the temperature limit of a semiconductor device made of silicon.

### BRIEF DESCRIPTION OF DRAWINGS

FIG. 1 is a circuit diagram of the temperature raising device in accordance with an embodiment;

FIG. 2A is a characteristic chart schematically illustrating transmission characteristics of a MOSFET; FIG. 2B is a characteristic chart schematically illustrating output characteristics of a MOSFET;

FIG. 3 is a characteristic chart exemplifying an output characteristic of a MOSFET;

FIG. 4 is an explanatory chart schematically illustrating temperature dependences of threshold voltages of MOSFETs;

FIGS. 5A and 5B are front and right-side views schematically illustrating the exterior of the MOSFET, respectively;

FIGS. 6A and 6B are front and right-side views schematically illustrating the exterior of a semiconductor device to be tested, respectively; and

FIG. 7 is a set of explanatory views for explaining methods of joining the MOSFET and the semiconductor device to be tested to each other.

### DESCRIPTION OF EMBODIMENTS

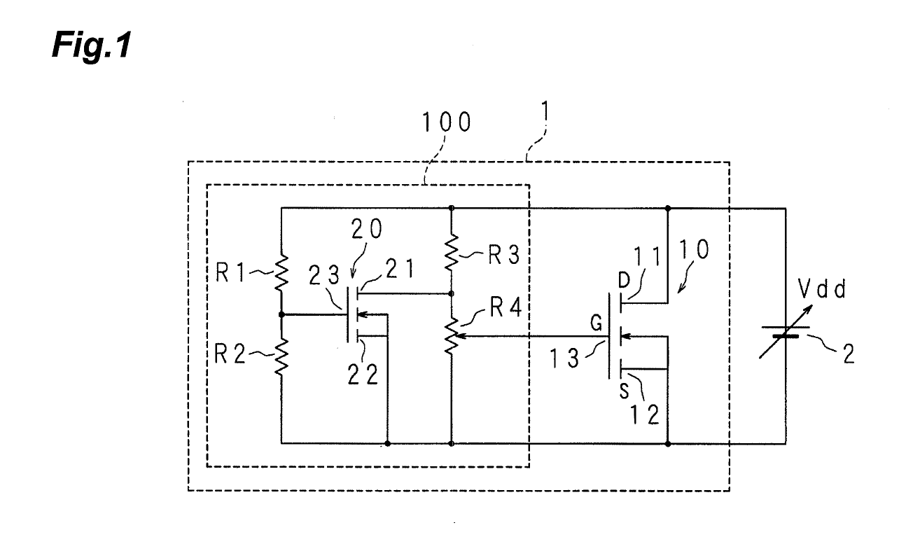

In the following, the present invention will be explained in detail with reference to the drawings illustrating its embodiments. FIG. 1 is a circuit diagram of the temperature raising device in accordance with an embodiment. In the drawing, 1 is the temperature raising device. The temperature raising device 1 is equipped with a MOSFET 10 having a drain electrode (D) 11 and a source electrode (S) 12 between which a variable voltage is fed from an external DC power supply 2. The MOSFET 10 is of the N-channel enhancement type, whose semiconductor material is constituted by silicon carbide (SiC). The temperature raising device 1 is also equipped with a bias circuit 100 which applies a bias voltage generated from the voltage fed between the drain electrode 11 and source electrode 12 (hereinafter referred to as power supply voltage Vdd) to a gate electrode (G) 13 of the MOSFET 10. The semiconductor material of the MOSFET 10 may be any typical inexpensive semiconductor as long as it is a so-called wide-bandgap semiconductor without being restricted to silicon carbide, but is preferably silicon carbide in view of the necessity for attaining a higher upper limit for the temperature that can be raised.

The bias circuit 100 has two sets of resistors R1, R2 and resistors R3, R4, each dividing the power supply voltage Vdd, and a source-grounded MOSFET 20 having a gate electrode 23 and a drain electrode 21, which are connected to a junction between the resistors R1, R2 and a junction between the resistors R3, R4, respectively. The MOSFET 20 is of the N-channel enhancement type, whose semiconductor material is constituted by silicon. The resistor R4 is a variable resistor in which a terminal joined to a slider is connected to the gate electrode 13 of the MOSFET 10. By adjusting the position of the slider of the resistor R4, an operator can change the bias voltage applied to the gate electrode 13 of the MOSFET 10.

In the circuit structure mentioned above, the gate voltage Vgs applied to the gate electrode 23 of the MOSFET 20 is represented by the following expression (1):

Vgs=Vdd×R2/(R1+R2) (1)

When the MOSFET 20 is turned off, the drain voltage Vds(OFF) applied to the drain electrode 21 and the drain resistor R seen from the drain electrode 21 are represented by the following expressions (2) and (3), respectively, according to the Ho-Thévenin's theorem:

Vds(OFF)=Vdd×R4/(R3+R4) (2)

Rd=R3×R4/(R3+R4) (3)

On the other hand, the drain voltage Vds in the case where a drain current Id flows into the MOSFET 20 when the gate voltage Vgs represented by the expression (1) is applied to the gate electrode 23 of the MOSFET 20 is represented by the following expression (4):

Vds=Vds(OFF)−Rd×Id (4)

In order to prevent the drain voltage Vds represented by the expression (4) from changing when the power supply voltage Vdd is changed by ΔVdd, the change in both sides of the expression (4) is required to be represented by the following expression (5), which is deformed into the following expression (6):

0=ΔVds(OFF)−Rd×ΔId (5)

ΔVds(OFF)=Rd×ΔId (6)

Next, substituting the change of the expression (2) and the expression (3) into the expression (6) yields the following expression (7), and eliminating R4/(R3+R4) from both sides of the expression (7) yields the following expression (8):

ΔVdd×R4/(R3+R4)=R3×R4/(R3+R4)×ΔId (7)

ΔVdd=R3×ΔId (8)

Since the transconductance gm of the MOSFET 20 is represented by the following expression (9), the following expression (10) is obtained by substituting the expression (9) into the expression (8), and the following expression (11) is obtained by substituting the change of the expression (1) into the expression (10) and eliminating ΔVdd from both sides.

gm=ΔId/ΔVgs (9)

ΔVdd=R3×gm×ΔVgs (10)

1=R3×gm×R2/(R1+R2) (11)

That is, it is seen that selecting the values of the resistors R1 to R3 such as to satisfy the expression (11) can make the drain voltage Vds unchangeable regardless of changes in the power supply voltage Vdd. When the values of the resistors R1 to R3 are thus selected, the bias voltage applied to the gate electrode 13 of the MOSFET 10 is determined by the position of the slider of the resistor R4 alone after the MOSFET 20 is turned on.

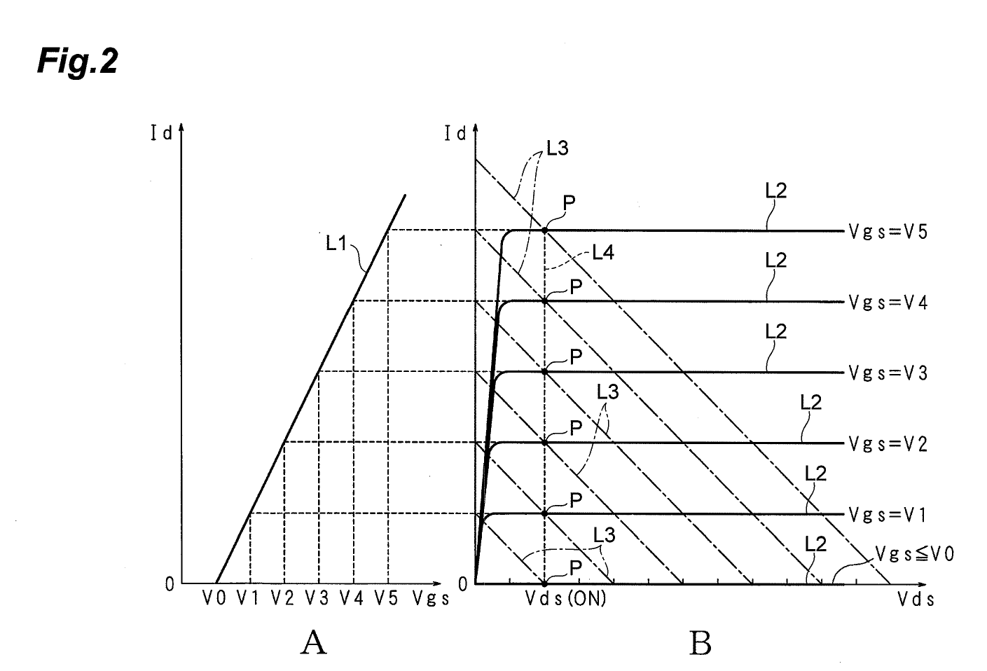

How the drain voltage Vds becomes constant regardless of changes in the power supply voltage Vdd will now be explained with reference to the drawings. FIGS. 2A and 2B are characteristic charts schematically illustrating transmission and output characteristics of a MOSFET 20, respectively. In FIG. 2A, the abscissa and ordinate indicate the gate voltage Vgs and drain current Id, respectively. In FIG. 2B, the abscissa and ordinate indicate the drain voltage Vds and drain current Id, respectively.

In FIG. 2A, a solid line L1 indicates that the MOSFET 20 is turned on when the gate voltage Vgs becomes V0, while the gradient of the solid line L1 corresponds to the transconductance. In FIG. 2B, solid lines L2 show change characteristics of the drain current Id with respect to the drain voltage Vds when the gate voltage Vgs is constant (V1 to V5), while dash-single-dot lines L3 represent load lines determined by the drain voltage Vds(OFF) at the time when the MOSFET 20 is turned off and the drain resistance Rd. According to the expression (4), the abscissa- and ordinate-intercepts of each load line correspond to the drain voltage Vds(OFF) and the value obtained by dividing the drain voltage Vds(OFF) by the drain resistance Rd, respectively.

In FIG. 2B, the intersection P between the output characteristic represented by the solid line L2 and load line represented by the dash-single-dot line L3 is an operating point, which moves to the upper left on the load line L3 in the chart when the gate voltage Vgs increases with respect to one load line L3 (i.e., when the solid line L2 indicating the output characteristic moves in the ordinate direction). When the load line L3 moves in the abscissa direction in the case where the gate voltage Vgs is made constant so as to fix the solid line L2 indicating the output characteristic, the operating point moves rightward on the solid line L2 indicating the output characteristic at that time in the chart.

In this embodiment, on the other hand, the gate voltage Vgs and the drain voltage Vds(OFF), which is the abscissa-intercept of the load line L3, increase in proportion to the power supply voltage Vdd as respectively represented by the expressions (1) and (2). Therefore, when the power supply voltage Vdd increases, the load line L3 moves in the abscissa direction, so that the operating point moves rightward in the chart, while the solid line L2 indicating the output characteristic moves in the ordinate direction, whereby the operating point moves to the upper left on the load line L3 in the chart. Appropriately adjusting the ratios by which the operating point thus moves rightward and to the upper left allows the operating point to move in the ordinate direction (i.e., upward) when the power supply voltage Vdd increases. When thus adjusted, the above-mentioned expression (11) is assumed to hold, so that the operating point moves on a broken line L4 connecting the intersections P in FIG. 2B. This fixes the drain voltage Vds of the MOSFET 20 at Vds(ON).

Though FIG. 2A illustrates an ideal case where the MOSFET 20 attains a linear transmission characteristic, the gradient of the transmission characteristic tends to increase (forms a curve which is convex on the lower right side) as the gate voltage Vgs increases in practice, whereby the broken line L4 connecting the intersections P indicating the operating points becomes a curve which is convex on the right side in FIG. 2B. By using such a characteristic, on the other hand, the drain voltage Vds can be adjusted so as to decrease as the power supply voltage Vdd increases in a region where the power supply voltage Vdd is high, for example. This allows the bias voltage applied to the gate electrode 13 of the MOSFET 10 to be suppressed more in a region where the power supply voltage Vdd is high.

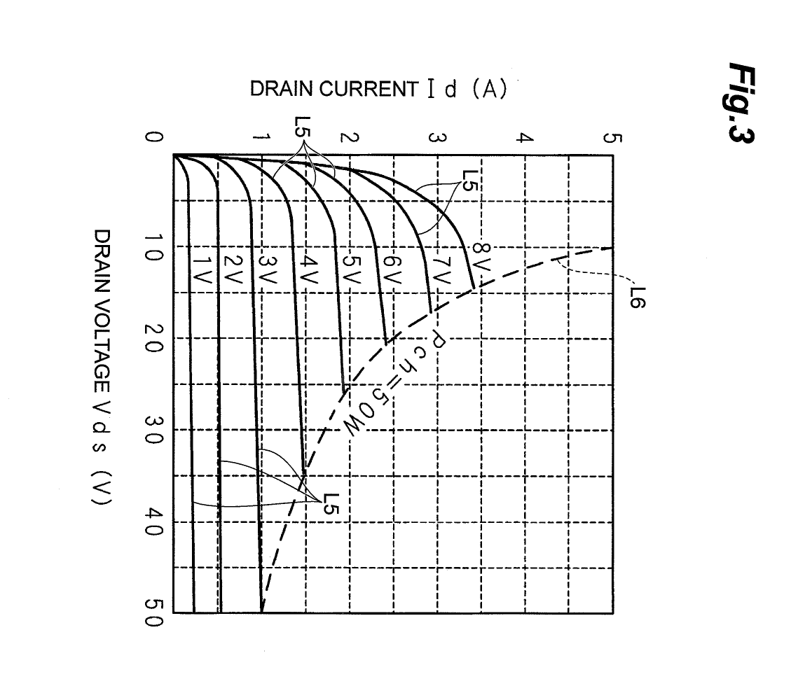

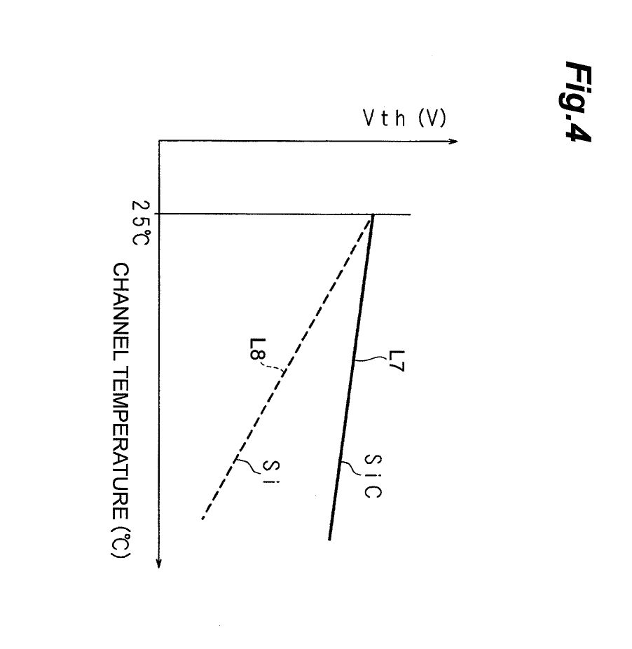

Characteristics of the MOSFET 10 will now be explained. FIG. 3 is a characteristic chart exemplifying an output characteristic of the MOSFET 10, while FIG. 4 is an explanatory chart schematically illustrating a temperature dependence of a threshold voltage of the MOSFET 10. In FIG. 3, the abscissa and ordinate indicate the drain voltage Vds and drain current Id, respectively. In FIG. 4, the abscissa and ordinate indicate the channel temperature and threshold voltage Vth, respectively. As illustrated in FIG. 1, the drain voltage Vds coincides with the power supply voltage Vdd.

In FIG. 3, solid lines L5 indicate change characteristics of the drain current Id with respect to the drain voltage Vds in the case where the gate voltage Vgs is constant (1 V to 8 V), while a broken line L6 indicates a boundary where a channel loss Pch=50 W. In practice, however, derating is required to be performed according to the rise in the channel temperature. A curve indicating the output characteristic in FIG. 3 is determined according to the bias voltage applied to the gate electrode 13 of the MOSFET 10, and the drain current Id of the MOSFET 10 is determined on this curve according to the drain voltage Vds equal to the power supply voltage Vdd at that time. This determines the channel loss of the MOSFET 10, and the Joule heat corresponding to this loss raises the temperature of the MOSFET 10.

When adjusting the temperature rise caused by the MOSFET 10 according to the magnitude of the bias voltage, in order to prevent the channel loss from exceeding its limit, the power supply voltage Vdd is preferably kept relatively low. When adjusting the temperature rise caused by the MOSFET 10 according to the magnitude of the power supply voltage Vdd, by contrast, the bias voltage is preferably kept relatively low. In this case, the channel loss is substantially in proportion to the power supply voltage Vdd. In either case, the MOSFET 10 operates not in the so-called linear region but in the saturation region.

In FIG. 4, a solid line L7 and a broken line L8 indicate threshold voltage characteristics of the MOSFET 10 and a MOSFET employing silicon (Si) as a semiconductor material, respectively. In FIG. 4, the abscissa indicates the channel temperature, while the ordinate represents the threshold voltage Vth when each MOSFET is turned on. When 25° C. is assumed to be a reference channel temperature, the threshold voltage Vth decreases at a rate of about −2 mV/° C. in an example of the MOSFET 10 whose semiconductor material is constituted by silicon carbide and at a rate of about −7 mV/° C. in an example of the MOSFET whose semiconductor material is constituted by silicon. They are equivalent to increases of about 0.2 V and 0.7 V in the bias voltage with respect to the rise of 100° C. in the channel temperature, respectively. Since this embodiment raises the channel temperature of the MOSFET 10 to about 300° C. as will be explained later, the MOSFET 10 is preferably constructed by a semiconductor material which makes the threshold voltage Vth fluctuate less, in particular, when the MOSFET 10 is operated in a region where the bias voltage is low in FIG. 3.

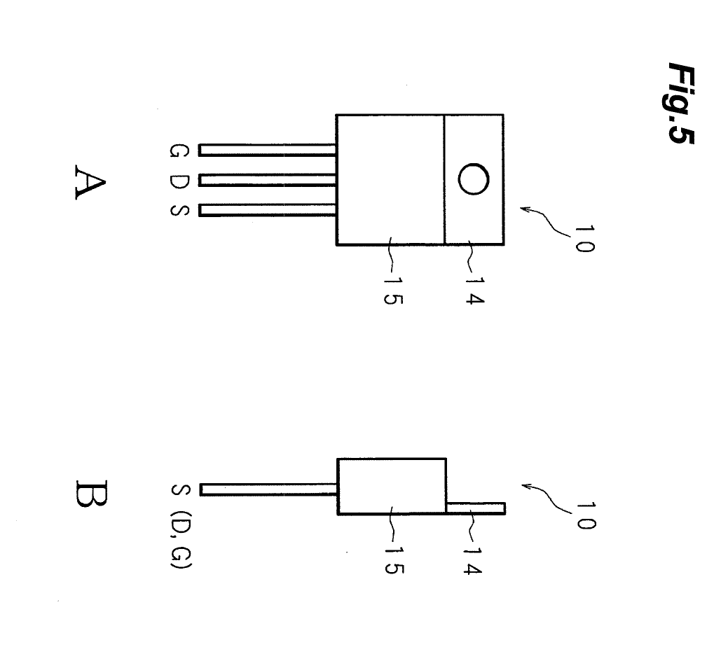

A method of raising the temperature of a semiconductor device to be tested by using the above-mentioned temperature raising device 1 will now be explained. FIGS. 5A and 5B are front and right-side views schematically illustrating the exterior of the MOSFET 10, respectively. The MOSFET 10 has a vertically long rectangular parallelepiped sealed body 15 made of an insulating resin, while leads (indicated by G, D, and S in the drawing; the same hereinafter) respectively connected to the gate electrode (G) 13, drain electrode (D) 11, and source electrode (S) 12 project downward from the lower part of the sealed body 15. From the upper part of the sealed body 15, a rectangular plate-shaped heat dissipater 14 having an attachment hole formed in its center part extends upward along the back face of the sealed body 15. The heat dissipater 14 is thermally in close contact with the drain electrode 11. When the heat dissipater 14 is not sealed with an insulating resin together with the sealed body 15, the heat dissipater 14 is electrically connected to the drain electrode 11.

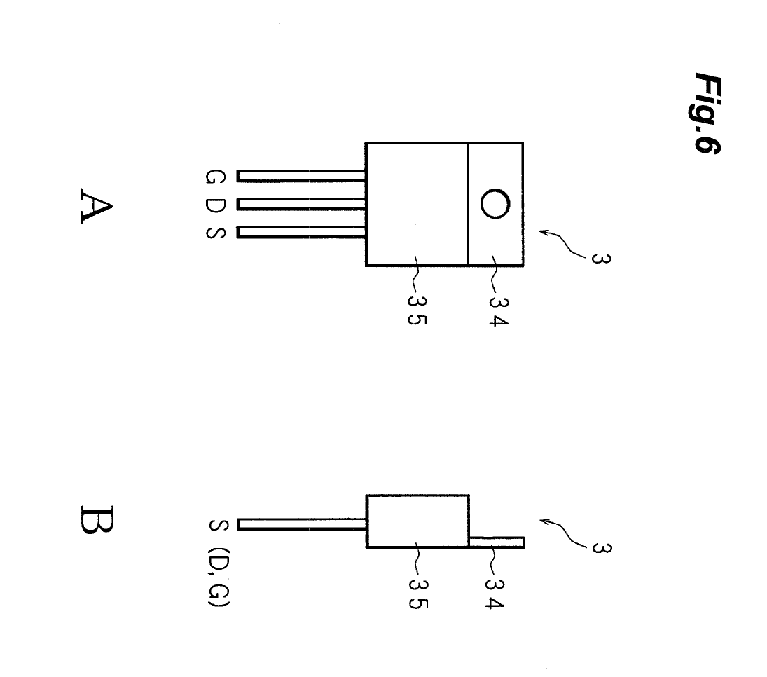

FIGS. 6A and 6B are front and right-side views schematically illustrating the exterior of a semiconductor device to be tested 3, respectively. The semiconductor device to be tested 3 is constituted by a MOSFET having a sealed body 35 with a heat dissipater 34 thermally in close contact with the drain electrode of the MOSFET. The sealed body 35 and heat dissipater 34 are constructed as with the sealed body 15 and heat dissipater 14, respectively, and the other structures are the same as those in the MOSFET 10, so that they will not be explained.

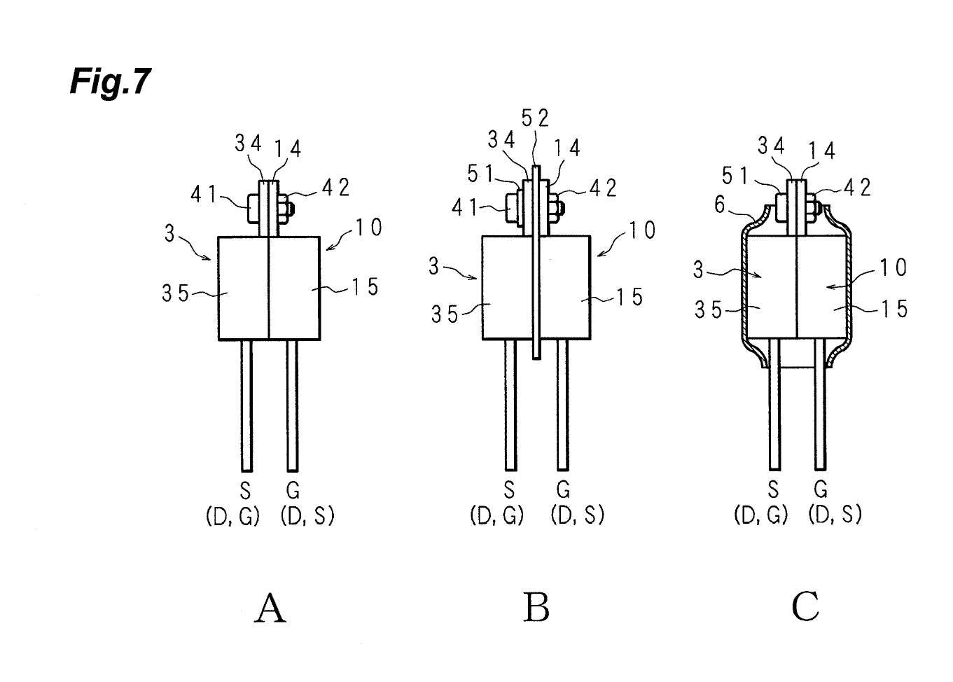

FIG. 7 is a set of explanatory views for explaining methods of joining the MOSFET 10 and the semiconductor device to be tested 3 to each other. FIG. 7A illustrates a joining method in the case where the heat dissipater 14 and sealed body 15 of the MOSFET 10 are integrally sealed with the insulating resin. The MOSFET 10 and the semiconductor device to be tested 3 butt their back faces against each other, while a screw 41 inserted through the attachment holes of the heat dissipaters 14, 34 is in threaded engagement with a nut 42. As a consequence, the heat dissipaters 14, 34 are fastened with the screw 41 and nut 42, so as to be thermally in close contact with each other. Hence, the semiconductor device to be tested 3 is heated efficiently when the MOSFET 10 raises its temperature.

FIG. 7B illustrates a joining method in the case where the heat dissipater 14 of the MOSFET 10 is not sealed with the insulating material. While the MOSFET 10 and the semiconductor device to be tested 3 butt their back faces against each other as in FIG. 7A, an insulator 52 is inserted (held) between the heat dissipaters 14, 34 in order to avoid electric interferences with the semiconductor device to be tested 3, since the heat dissipater 14 is electrically connected to the drain electrode 11. A mica sheet, which is excellent in thermal conductivity, is employed as the insulator 52, for example. The screw 41 is in threaded engagement with the nut 42 through an insulating washer 51 inserted in the attachment holes of the heat dissipaters 14, 34. This ensures electric insulation between the heat dissipaters 14, 34.

FIG. 7C illustrates a method using a heat-shrinkable tube in addition to the joining method depicted in FIG. 7A. In the drawing, 6 is the heat-shrinkable tube. The heat-shrinkable tube 6 surrounds the sealed body 15 of the MOSFET 10 and the sealed body 35 of the semiconductor device to be tested. Since the heat-shrinkable tube 6 is heated as appropriate, its upward and downward extending parts tilt inward, so as to surround a part of the heat dissipaters 14, 34 and a part of the leads. The heat-shrinkable tube 6 may surround the heat dissipaters 14, 34 as a whole, or other heat-insulating materials may surround the MOSFET 10 and semiconductor device to be tested 3 as a whole, for example. The MOSFET 10 and semiconductor device to be tested 3 may also be joined to each other by the shrinkage force of the heat-shrinkable tube 6 alone without using the screw 41 and nut 42.

When raising the temperature of the semiconductor device to be tested 3, it is heated by the MOSFET 10 of the temperature raising device 1 while using any of the three joining methods mentioned above. The leads (G, D, S) of the MOSFET 10 are connected as illustrated in the circuit diagram of FIG. 1 and fed with the power supply voltage Vdd and bias voltage from the DC power supply 2 and bias circuit 100, respectively. The leads (G, D, S) of the semiconductor device to be tested 3 are connected to an undepicted test circuit and driven so as to perform continuous switching at a high frequency of several hundred kHz, for example. The MOSFET 10 whose semiconductor material is constituted by silicon carbide can operate even when the channel temperature exceeds 400° C. The MOSFET 10 is heated to a high temperature of 300° C. or above in this embodiment as well, so as to raise the temperature of the semiconductor device to be tested 3. While the temperature of the semiconductor device to be tested 3 is displayed as detected by an undepicted temperature sensor, the operator rotates a controller for adjusting the slider of the resistor 4 or the power supply voltage Vdd of the DC power supply 2 with reference to the display, such that the semiconductor device to be tested 3 attains a predetermined temperature.

As in the foregoing, when the external DC power supply 2 feeds the power supply voltage Vdd to the drain electrode 11 of the MOSFET 10 constituted by silicon carbide (SiC) in this embodiment, a variable bias voltage generated from thus fed power supply voltage Vdd is applied to the gate electrode 13. This enables operations using a single external power supply, whereby the drain current is controlled variably according to a relatively small electric power. Therefore, the bias voltage is easily changed by a human operation, so that a drain current having a level corresponding to the magnitude of the bias voltage flows in from the external power supply, thereby generating a Joule heat corresponding to the product of the power supply voltage of the external power supply 2 and the drain current, thus raising the temperature of the drain electrode 11 and heat dissipater 14. Even when the temperature of the drain electrode 11 and heat dissipater 14 exceeds the tolerable temperature of a semiconductor made of silicon, the temperature raising device can operate stably up to near the limit temperature of silicon carbide constituting the MOSFET 10. Hence, the temperature raising device is not only small in size, inexpensive, and easy to control the temperature, but can also be employed for a temperature raising test at a temperature beyond the temperature limit of a semiconductor device made of silicon.

When the power supply voltage of the DC power supply 2 serving as a basis for generating the bias voltage changes, the bias voltage is produced through the slider of the resistor from a voltage (“Vds” in the expression (4)) obtained by adding the drain voltage (“Vds(OFF)” in the expression (4)) changing according to the magnitude of the power supply voltage and a voltage (“−Rd×Id” in the expression (4)) changing such as to cancel the change in the power supply voltage. That is, to the change (“ΔVds(OFF)” in the expression (5)) in the voltage divided from the power supply voltage of the DC power supply 2, a change in a voltage (“Vgs” in the expression (1)) divided separately from the power supply voltage is amplified by a predetermined negative amplification factor and then added (i.e., “ΔId” in the expression (9) is employed in “−Rd×ΔId” in the expression (5)), so as to cancel the change in the power supply voltage. This generates the bias voltage from a fixed drain voltage (Vds(ON) in the expression (4) and FIG. 2B), whereby a constant bias voltage is applied to the gate electrode 12 regardless of the change in the power supply voltage from the external power supply 2.

Since the MOSFET 10 operates in the saturation region, the Joule heat generated at the drain electrode 11 becomes substantially proportional to the power supply voltage of the external power supply 2 fed to the drain electrode 11.

When the heat dissipater 14 is molded with a resin, electric interferences can be prevented from occurring even when the heat dissipater 14 is joined to a metal part of the semiconductor device to be tested 3.

When the insulator 52 electrically insulates the heat dissipater 14, inserting the insulator 52 between a metal part of the semiconductor device to be tested 3 and the heat dissipater 14 can prevent electric interferences from occurring.

The power supply voltage of the DC power supply 2 is fed to the drain electrode 11 of the MOSFET 10 of the temperature raising device 1 and, while joining the heat dissipater 14 of the MOSFET 10 and the heat dissipater 34 of the semiconductor device to be tested 3 to each other, at least one of the power supply voltage of the DC power supply 2 and the bias voltage to be applied to the gate electrode 12 of the MOSFET 10 is changed, so as to adjust how much the temperature is raised. This can efficiently transmit the heat generated by the temperature raising device 1 to the semiconductor device to be tested 3. When the power supply voltage of the external power supply 2 and/or the bias voltage is changed to become higher/lower, the quantity of the Joule heat generated at the drain electrode 11 of the MOSFET 10 becomes greater/smaller, so that the semiconductor device to be tested 3 is heated more/less through the heat dissipaters.

The MOSFET 10 of the temperature raising device 1 and the semiconductor device to be tested 3 are surrounded with the heat-shrinkable tube 6, which is then heated to shrink. This joins the MOSFET 10 and the semiconductor device to be tested 3 closely to each other and reduces the ratio of heat diffusing to the outside air in the Joule heat generated in the MOSFET 10, thereby improving the temperature raising effect.

It should be noted that the above-mentioned embodiments are illustrative but not restrictive in all aspects. The scope of the present invention is set forth not by the above explanation but by Claims, and it is intended to include all changes which fall within meanings and scopes equivalent to Claims.

### INDUSTRIAL APPLICABILITY

The present invention can be utilized as a temperature raising device which is not only small in size, inexpensive, and easy to control the temperature, but can also be employed for a temperature raising test at a temperature beyond the temperature limit of a semiconductor device made of silicon and as a temperature raising test method using the temperature raising device.

### REFERENCE SIGNS LIST

1 temperature raising device
10 MOSFET
11 drain electrode
13 gate electrode
14 heat dissipater
100 bias circuit
20 MOSFET
21 drain electrode
23 gate electrode
R1, R2, R3, R4 resistor
2 DC power supply
3 semiconductor device to be tested
34 heat dissipater
41 screw
42 nut
51 insulating washer
52 insulator
6 heat-shrinkable tube

1. A temperature raising device comprising a MOSFET having a heat dissipater with a drain electrode to be fed with a voltage from an external DC power supply and a bias circuit for applying a bias voltage to a gate electrode of the MOSFET;
wherein the MOSFET is made of a semiconductor material having a bandgap greater than that of silicon; and
wherein the bias circuit generates a variable bias voltage from the voltage to be fed to the drain electrode.

2. A temperature raising device according to claim 1, wherein the DC power supply has a variable output voltage; and
wherein the bias circuit generates the bias voltage from a voltage obtained by adding a voltage corresponding to a change in the output voltage and a voltage for canceling the change.

3. A temperature raising device according to claim 2, wherein the MOSFET operates in a saturation region.

4. A temperature raising device according to claim 1, wherein the heat dissipater is molded with a resin.

5. A temperature raising device according claim 1, further comprising an insulator for electrically insulating the heat dissipater.

6. A temperature raising test method for conducting a temperature raising test of a semiconductor device having a heat dissipater by using the temperature raising device according to claim 1 and a DC power supply having a variable output voltage, the method comprising:
feeding the output voltage of the DC power supply to the drain electrode of the MOSFET constituting the temperature raising device;
joining the heat dissipaters of the drain electrode of the MOSFET and semiconductor device to each other; and
changing the output voltage and/or the bias voltage applied to the gate electrode of the MOSFET.

7. A temperature raising test method according to claim 6, wherein the MOSFET and the semiconductor device are surrounded with a heat-shrinkable tube.
